(19) United States
(12) Patent Application Publication
(10) Pub. No.: US 2016/0124058 A1
(43) Pub. Date: May 5, 2016

(54) RF ASSEMBLY FOR AN MRD DEVICE COMPRISING A SURFACE AND A VOLUME COIL

(71) Applicant: ASPECT IMAGING LTD., Shoham (IL)

(72) Inventor: Uri RAPOPORT, Moshav Ben Shemen (IL)

(73) Assignee: ASPECT IMAGING LTD., Shoham (IL)

(21) Appl. No.: 14/922,218

(22) Filed: Oct. 26, 2015

Related U.S. Application Data
(60) Provisional application No. 62/074,113, filed on Nov. 3, 2014.

(51) Int. Cl. G01R 33/34; G01R 33/56; G01R 33/341

(52) U.S. Cl. CPC G01R 33/34046; G01R 33/34084; G01R 33/341; G01R 33/5608

(57) ABSTRACT

A magnetic resonance imaging device (MRD) comprising an RF assembly which has both a volume coil and a surface coil. The coils are simultaneously operable, so that they can be used in a number of ways. These include: both functioning as transceivers; the volume coil functioning as a transceiver and the surface coil as a receiver; the volume coil functioning as a transceiver and the surface coil as a transmitter; both the volume coil and the surface coil functioning as receivers; the volume coil functioning as a receiver and the surface coil as a transceiver; the volume coil functioning as a receiver and the surface coil as a transmitter; both the volume coil and the surface coil functioning as transmitters; the volume coil functioning as a transmitter and the surface coil as a transceiver; and the volume coil functioning as a transmitter and the surface coil as a receiver.

### FIELD OF THE INVENTION

The present invention relates to an RF assembly comprising at least one surface coil and at least one volume coil which act together either as transmitters, receivers, transceivers or any combination of these functions. The invention additionally relates to an MRD comprising the RF assembly as well as to a method of manufacturing the assembly.

### BACKGROUND OF THE INVENTION

U.S. Pat. No. 6,751,496 to Su et al discloses an inherently de-coupled sandwiched solenoidal array coil (SSAC) for use in receiving nuclear magnetic resonance (NMR) radio frequency (RF) signals in both horizontal and vertical-field magnetic resonance imaging (MRI) systems. In its most basic configuration, the SSAC comprises two coaxial RF receive coils. The first coil of the array has two solenoidal (or loop) sections that are separated from one another along a common axis. The two sections are electrically connected in series but the conductors in each section are wound in opposite directions so that a current through the coil sets up a magnetic field of opposite polarity in each section. The second coil of the SSAC is disposed (“sandwiched”) between the two separated solenoidal sections of the first coil in a region where the combined opposing magnetic fields cancel to become a null. Due to the winding arrangement and geometrical symmetry, the receive coils of the array become electromagnetically “de-coupled” from one another while still maintaining their sensitivity toward receiving NMR signals. The multiple coil array arrangement also allows for selecting between a larger or smaller field-of-view (FOV) to avoid image fold-over problems without time penalty in image data acquisition. Alternative embodiments are disclosed which include unequal constituent coil diameters, unequal constituent coil windings, non-coaxial coil configurations, a three-coil quadrature detection (QD) SSAC arrangement, multiple SSAC arrangements, and optimized SSAC configurations for breast imaging in both horizontal and vertical-field MRI systems.

However the axes of the coils of U.S. Pat. No. 6,751,496 are all parallel to each other.

It is therefore a long felt need to provide a system and method for simultaneously measuring mutually perpendicular components of the RF magnetic field during MRI of an infant using non-parallel coils.

### SUMMARY

A magnetic resonance imaging device (MRD) comprising an RF assembly; said RF assembly is characterized by at least one volume coil and at least one surface coil which are simultaneously operable so that one of the following is being held true:

said volume coil and said surface coil as transceivers;
said volume coil as transceiver and said surface coil as receiver;
said volume coil as transceiver and said surface coil as transmitter;
said volume coil and said surface coil as receivers;
said volume coil as receiver and said surface coil as transceiver;
said volume coil as receiver and said surface coil as transmitter;
said volume coil and said surface coil as transmitters;
said volume coil as transmitter and said surface coil as transceiver; and
said volume coil as transmitter and said surface coil as receiver.

According to an embodiment of the present invention, the MRD has an SNR value n times higher than an SNR value of an MRD comprising an RF assembly comprising only a volume coil or a surface coil; n is equal or greater than 1.05.

According to an embodiment of the present invention, wherein the imaging time of the MRD is m times lower than an SNR value of an MRD comprising RF assembly comprising only a volume coil or a surface coil; m is equal or greater than 1.05.

According to an embodiment of the present invention, wherein the volume coil is selected from a group consisting of birdcage coils, TEM Coil, saddle coil, and any combination thereof.

According to an embodiment of the present invention, wherein the RF assembly is maneuverable.

According to an embodiment of the present invention, wherein the volume coil and the surface coil are individually maneuverable.

According to an embodiment of the present invention, wherein at least one of the volume coil or the surface coil are multi tuned RF coils.

According to an embodiment of the present invention, wherein the MRD additionally comprises an incubator adapted to accommodate a neonate.

An RF assembly for magnetic resonance imaging device (MRD) characterized by at least one volume coil and at least one surface coil which are simultaneously operable so that one of the following is being held true:

said volume coil and said surface coil as transceivers;
said volume coil as transceiver and said surface coil as receiver;
said volume coil as transceiver and said surface coil as transmitter;
said volume coil and said surface coil as receivers;
said volume coil as receiver and said surface coil as transceiver;
said volume coil as receiver and said surface coil as transmitter;
said volume coil and said surface coil as transmitters;
said volume coil as transmitter and said surface coil as transceiver; and
said volume coil as transmitter and said surface coil as receiver.

According to an embodiment of the present invention, wherein the MRD comprising the RF assembly has an SNR value n times higher than an SNR value of an MRD comprising an RF assembly comprising only a volume coil or a surface coil; n is equal or greater than 1.05;

According to an embodiment of the present invention, wherein the imaging time of the MRD comprising the RF assembly value is m times lower than an SNR value of an MRD comprising an RF assembly comprising only a volume coil or a surface coil; m is equal or greater than 1.05.

According to an embodiment of the present invention, wherein the volume coil is selected from a group consisting of birdcage coils, TEM Coil, saddle coil, and any combination thereof.

According to an embodiment of the present invention, wherein the RF assembly is combined within a neonate incubator adapted to be accommodated within an MRD.

According to an embodiment of the present invention, wherein the RF assembly is combined within the MRD.

According to an embodiment of the present invention, wherein the volume coil is combined within the MRD or within a neonate incubator adapted to be accommodated within the MRD and the surface coil is combined within the MRD or within the incubator.

According to an embodiment of the present invention, wherein the volume coil or the surface coil is configured to close an opening of the incubator.

According to an embodiment of the present invention, wherein the RF assembly is maneuverable.

According to an embodiment of the present invention, wherein the volume coil and the surface coil are individually maneuverable.

According to an embodiment of the present invention, wherein at least one of the volume coil or the surface coil are multi tuned RF coils.

According to an embodiment of the present invention, wherein at least one of the volume coil or the surface coil are multi tuned RF coils.

According to an embodiment of the present invention, a method for manufacturing an RF assembly a for magnetic resonance imaging device (MRD) comprising steps of: obtaining at least one volume coil and at least one surface coil; combining said at least one volume coil and said at least one surface coil; wherein said at least one volume coil and said at least one surface coil are simultaneously operable so that one of the following is being held true:

said volume coil and said surface coil as transceivers;
said volume coil as transceiver and said surface coil as receiver;
said volume coil as transceiver and said surface coil as transmitter;
said volume coil and said surface coil as receivers;
said volume coil as receiver and said surface coil as transceiver;
said volume coil as receiver and said surface coil as transmitter;
said volume coil and said surface coil as transmitters;
said volume coil as transmitter and said surface coil as transceiver;
said volume coil as transmitter and said surface coil as receiver.

According to an embodiment of the present invention, wherein the MRD comprising the RF assembly has an SNR value n times higher than an SNR value of an MRD comprising an RF assembly comprising only a volume coil or a surface coil; n is equal or greater than 1.05;

According to an embodiment of the present invention, wherein the imaging time of the MRD comprising the RF assembly value is m times lower than an SNR value of an MRD comprising an RF assembly comprising only a volume coil or a surface coil; m is equal or greater than 1.05.

According to an embodiment of the present invention, additionally comprising a step of selecting the volume coil from a group consisting of birdcage coils, TEM Coil, saddle coil, and any combination thereof.

According to an embodiment of the present invention, additionally comprising a step of combining the RF assembly a neonate incubator adapted to be accommodated within an MRD.

According to an embodiment of the present invention, additionally comprising a step of combining the RF assembly within the MRD.

According to an embodiment of the present invention, additionally comprising a step of combining the volume coil within the MRD or within a neonate incubator adapted to be accommodated within the MRD and combining the surface coil within the MRD or within the incubator.

According to an embodiment of the present invention, additionally comprising a step of configuring the volume coil or the surface coil to close an opening of the incubator.

According to an embodiment of the present invention, wherein the RF assembly is maneuverable.

According to an embodiment of the present invention, wherein the volume coil and the surface coil are individually maneuverable.

According to an embodiment of the present invention, wherein at least one of the volume coil or the surface coil are multi tuned RF coils.

According to an embodiment of the present invention, a method for imaging a patient with an MRD device, comprising steps of: (a) obtaining an MRD device comprising at least two RF coils; said at least two RF coils comprise at least one volume coil and at least one surface coil; and, (b) operating the same; wherein said at least one volume coil and said at least one surface coil are simultaneously so that one of the following is being held true:

said volume coil and said surface coil as transceivers;
said volume coil as transceiver and said surface coil as receiver;
said volume coil as transceiver and said surface coil as transmitter;
said volume coil and said surface coil as receivers;
said volume coil as receiver and said surface coil as transceiver;
said volume coil as receiver and said surface coil as transmitter;
said volume coil and said surface coil as transmitters;
said volume coil as transmitter and said surface coil as transceiver;
said volume coil as transmitter and said surface coil as receiver.

According to an embodiment of the present invention, wherein said MRD comprising said RF assembly has an SNR value n times higher than an SNR value of an MRD comprising an RF assembly comprising only a volume coil or a surface coil; n is equal or greater than 1.05;

According to an embodiment of the present invention, wherein the imaging time of said MRD comprising said RF assembly value is m times lower than an SNR value of an MRD comprising an RF assembly comprising only a volume coil or a surface coil; m is equal or greater than 1.05.

According to an embodiment of the present invention, additionally comprising a step of selecting said volume coil from a group consisting of birdcage coils, TEM Coil, saddle coil, and any combination thereof.

According to an embodiment of the present invention, additionally comprising a step of combining said RF assembly a neonate incubator adapted to be accommodated within an MRD.

According to an embodiment of the present invention, additionally comprising a step of combining said RF assembly within said MRD.

According to an embodiment of the present invention, additionally comprising a step of combining said volume coil within said MRD or within a neonate incubator adapted to be accommodated within said MRD and combining said surface coil within said MRD or within said incubator.

According to an embodiment of the present invention, additionally comprising a step of configuring said volume coil or said surface coil to close an opening of said incubator.

According to an embodiment of the present invention, wherein said RF assembly is maneuverable.

According to an embodiment of the present invention, wherein said volume coil and said surface coil are individually maneuverable.

According to an embodiment of the present invention, wherein at least one of said volume coil or said surface coil are multi tuned RF coils.

### BRIEF DESCRIPTION OF THE FIGURES

In order to understand the invention and to see how it may be implemented in practice, a plurality of embodiments will now be described, by way of non-limiting example only, with reference to the accompanying drawings, in which:

FIG. 1 is an illustration representing surface RF coils;

FIGS. 2A-C illustrate different volume RF coils, where:

FIG. 2A is an illustration representing a birdcage coil;

FIG. 2B is an illustration representing a saddle coil;

FIG. 2C is an illustration representing a solenoidal coil;

FIG. 3A is an illustration representing the B1 field of a 6 runged birdcage coil;

FIG. 3B is an illustration representing the B1 field of a surface coil;

FIG. 4A is an illustration representing an RF assembly comprising a volume coil;

FIG. 4B is an illustration representing an RF assembly comprising a surface coil;

FIG. 4C is an illustration representing an RF assembly comprising a surface coil and a volume coil;

FIG. 4D is an illustration representing an MRD device with a cylindrical magnet electromagnet comprising an RF assembly of combined surface coil and a volume coil;

FIG. 4E is an illustration representing an MRI device with a dipolar electromagnet comprising an RF assembly of combined surface coil and a volume coil.

### DETAILED DESCRIPTION OF THE PREFERRED EMBODIMENTS

In the following detailed description of the preferred embodiments, reference is made to the accompanying drawings that form a part hereof, and in which are shown by way of illustration specific embodiments in which the invention may be practiced. It is understood that other embodiments may be utilized and structural changes may be made without departing from the scope of the present invention. The present invention may be practiced according to the claims without some or all of these specific details. For the purpose of clarity, technical material that is known in the technical fields related to the invention has not been described in detail so that the present invention is not unnecessarily obscured.

The present invention relates to an RF assembly for an MRD that combines a surface coil with a volume which both serve as transceivers. Combining the two coils results in improved SNR as well as reduced imaging time. Each coil may act as a transceiver Rf coil and/or a receiver RF coil and/or a transmitter RF coil.

MRI relies on the detection of NMR signals from abundant hydrogen protons in the human body. These protons are first subjected to a strong radio frequency (RF) electromagnetic wave excitation pulse. If the frequency of the excitation pulse is properly chosen, the protons receive sufficient RF energy to make a transition to an excited state. Eventually, the excited protons give up their excess energy via a decay process, commonly known as “relaxation”, and return to their original state.

Since the magnetic moment of a proton is a vector quantity, the microscopic behavior of millions of protons considered together is equivalent to the vector sum of the individual magnetic moments of all the protons. For convenience, this sum is typically represented as a single resultant magnetization vector, MO, which is aligned with B0 (the static main magnetic field). The strong RF excitation pulse used in MRI effectively tips this resultant magnetization vector away from alignment with the static main field B0 and causes it to precess before decaying back to an equilibrium alignment with B0. The component of this precessing resultant magnetization vector in a plane perpendicular to B0 induces an RF signal, referred to as the nuclear magnetic resonance (NMR) signal, in RF receiver coil(s) placed near the body portion containing the excited protons.

During clinical MRI, the magnetic resonance of protons in different tissues within an anatomical region are made distinguishable through the evocation of a magnetic field gradient along each of three mutually orthogonal spatial directions, the effect of which is to cause protons at different spatial locations to have slightly different NMR frequencies. The NMR signals induced in the receiver coil can then be processed to reconstruct images of the anatomical structures of interest (i.e., images of the spatial distribution of NMR nuclei which, in many respects, conform to the anatomical structures containing such nuclei).

To obtain the maximum induced signal in a receiver coil, the magnetic field of the receiver coil, conventionally designated as B1, must be oriented perpendicular to the direction of the static main magnetic field (B0) of the MRI apparatus. For a planar-loop (i.e., a substantially flat loop) type receive coil, that direction is in a direction normal to the plane of the conductive loop(s) of the coil.

For a quadrature detection (QD) type coil—which basically consists of two RF receive coils having mutually perpendicularly oriented B1 fields—must also have the B1 fields of both of its coils oriented perpendicular to the MRI apparatus static field B0 to obtain a maximum induced signal.

In clinical MRI, there are certain design considerations that are particularly relevant toward obtaining maximum performance from an RF receive coil. For example, the NMR signals induced in an RF receive coil during magnetic resonance imaging are nominally on the order of nanovolts in magnitude while the background ambient electrical noise may be of comparable levels or higher. Therefore, a high performance RF receive coil for clinical MRI needs to be electromagnetically sensitive enough to detect the low-level NMR signals despite the relatively high levels of background electrical noise. Moreover, other design considerations such as field-of-view, uniformity (i.e., uniformity of the magnetic field generated by the coil) and coil efficiency are also highly relevant to coil performance in the clinical MRI environment; uniformity because it can affect image interpretation and coil efficiency because a highly efficient coil allows the same image signal information to be acquired in a shorter time.

Theoretical analysis and experimental results have indicated that for many MRI applications, using a plurality of RF receiver coils as a signal receiving array is advantageous for improving coil sensitivity, signal-to-noise ratio and imaging field-of-view. Conventionally, the imaging “field-of-view” (FOV) for an MRI receiver coil is defined as the distance between the two points on the coil sensitivity profile (i.e., a graph of coil sensitivity vs. distance profile) where the signal drops to 80% of its peak value. In a typical MRI receiver coil array arrangement, instead of using a single large FOV but less sensitive coil that covers the entire imaging volume of interest, multiple small FOV, sensitive coils are distributed as an array over the entire imaging volume. Each individual coil of the array covers a small localized volume and the NMR signals received by each coil are simultaneously acquired through corresponding data acquisition channels. Signals from each of the channels are then appropriately combined and processed to construct an image of the complete volume of interest. Due to this ability to simultaneously acquire a signal from multiple sources (i.e., multiple coils) and since each individual signal channel is provided with its own associated detection circuitry, an array type coil can operate with high efficiency.

Typically, in prior-art devices, the coils have parallel axes. In the present invention, the axes of the coils can be non-parallel, allowing greater sensitivity when flips of other than 90° are used.

There are two major types of RF coils: volume coils and surface coils. Volume coils are configured to provide a homogeneous RF excitation across a large volume. Most clinical MRI scanners include a built in volume coil to perform whole-body imaging, and smaller volume coils have been constructed for the head and other extremities. These coils require a great deal of RF power because of their size, so they are often driven in quadrature in order to reduce by two the RF power requirements. Further, volume coils are undesirable when scanning a small area because they receive noise from the entire volume, not just the region of interest.

The term “RF” or “radio frequency” interchangeably refers hereinafter to any frequency within the electromagnetic spectrum associated with radio wave propagation. The RF usually used in magnetic resonance study is in the megahertz (MHz) range. The RF range commonly used in electron spin resonance is in the gigahertz (GHz).

The term “RF coil” refers hereinafter to any coil used for transmitting RF pulses and/or receiving MR signals used for magnetic resonance imaging. RF coils are known in the art to be used in magnetic resonance configurations such as “birdcage coil”, “saddle coil”, “solenoid coil”, and the like.

The term “surface coil” refers hereinafter to coils designed to provide a very high RF sensitivity over a small region of interest. These coils are often single or multi-turn loops which are placed directly over the anatomy of interest. The size of these coils can be optimized for the specific region of interest.

The term “volume coil” refers hereinafter to coils designed to provide a homogeneous RF excitation across a large volume. Most clinical MRI scanners include a built in volume coil to perform whole-body imaging, and smaller volume coils have been constructed for the head and other extremities. Common designs for volume coils include Birdcage Coils, TEM Coils, and Saddle Coils. These coils require a great deal of RF power because of their size, so they are often driven in quadrature in order to reduce by two the RF power requirements. The RF homogeneity of volume coils is highly desirable for transmit, but is less ideal when the region of interest is small. The large field of view of volume coils means that during receive they receive noise from the whole body, not just the region of interest. Surface coils make poor transmit coils because they have poor RF homogeneity, even over their region of interest. Their small field of view makes them ideal for receive, as they only detect noise from the region of interest.

The birdcage coil is the most commonly used RF-transmit device used in clinical MRI today. Virtually all body coils in cylindrical superconducting scanners are of this design. As shown in the diagram (above left), the birdcage coil consists of two circular conductive loops referred to as end rings connected by an even number of conductive straight elements called rungs or legs. The number of rungs depends on the size of the coil (body coil>head coil) and typically ranges from about 8 to 32. Birdcage coils also contain capacitors between conducting elements variably arranged based on the frequency characteristics desired. In clinical MRI a high-pass configuration is generally used with pairs of capacitors located along the end rings. Together this design approximates a continuous conducting surface.

In transmit operation sinusoidal currents are applied to each rung that are sequentially phase shifted around the coil's periphery. If there are N rungs, the phase shift between the currents in neighboring elements is 360°/N. According to antenna theory whenever the current distribution over a cylindrical surface satisfies sinusoidal angular dependence, a resonant condition exists and a homogeneous magnetic field can be created inside the conductor.

Some insight into the generation of a circularly polarized B1 field can be appreciated by considering the diagram below showing a hypothetical 6-rung birdcage coil. The current in each rung is directed into the page (denoted by X arrow ends). The curved local fields generated around each rung are drawn according to Maxwell's right-hand rule. Each rung is driven by a sinusoidal current, but the peak current of each successive rung is delayed by 360°/6=60°. As each rung peaks in turn the central magnetic field is seen to rotate. This is an RF-resonance phenomenon called the first mode, or homogeneous mode of the coil.

The term “signal to noise ratio (SNR)” refers hereinafter to a generic term, which measure how much true signal (e.g. reflecting actual anatomy) versus how much noise (e.g. random quantum mottle) a particular image has, which results in a grainy appearance. The SNR is measured frequently by calculating the difference in signal intensity between the area of interest and the background (usually chosen from the air surrounding the object). In air, any signal present should be noise. The difference between the signal and the background noise is divided by the standard deviation of the signal from the background—an indication of the variability of the background noise. SNR is proportional to the volume of the voxel and to the square root of the number or averages and phase steps (assuming constant sized voxels). Since averaging and increasing the phase steps takes time, SNR is related closely to the acquisition time.

The term “transceiver” refers hereinafter to a device comprising both a transmitter and a receiver which are combined and share common circuitry or a single housing.

The term “transceiver RF coil” refers hereinafter to an RF coil functioning both as a transmitter coil and a receiver coil.

The term “transmitter RF coil” refers hereinafter to the RF coil used in excitation of the spins.

Also called transmit-only coil it is used to create the B1 field. As a radio frequency generator send this coil bursts of RF pulses. These pulses serve to disturb the spins in the patient.

The term “receiver RF coil” refers hereinafter to an RF coil used to detect or receive the MR signal from the patient as the disturbed spins relax back into their equilibrium distribution.

The term “B1 field” refers hereinafter to varying radiofrequency (RF) field that is first transmitted into the spin system near the Larmor frequency. In addition to having specific frequency, the B1 field must also be applied perpendicular to the main magnetic field (Bo). The B1 field is produced by driving electrical currents through specialized RF-transmit coils. These coils are located either within the inner walls of the scanner or as free-standing devices connected by cables placed on or near the patient.

The term “imaging time” refers hereinafter to the time between the beginning of the imaging process until receiving satisfactory data.

The term “multi tuned RF coil” refers hereinafter to any RF coil designed to operate at more than one resonance frequency (providing different operational modes), so that the MR of more than one kind of nucleus can be observed with the same coil.

The term “incubator” interchangeably refers hereinafter to a special unit specializing in the care of ill or premature newborn infants. This includes a stationary incubator, a moveable incubator, a transport incubator, a disposable incubator, a healthcare facility incubator, portable incubator, an intensive care incubator, an incubator intended for home use, an incubator for imaging a neonate, a treatment incubator, a modular incubator, an isolating incubator and any combination thereof. The neonatal incubator is a box-like enclosure in which an infant can be kept in a controlled environment for observation and care. The incubator usually includes observation means to the accommodated neonate, and openings for the passage of life support equipment, and the handler's hands. At least partially enclosed environment formed within the incubator is at least partially isolated from the external environment conditions such as noise, vibration, drift, temperature, light, gas concentrations, humidity, microorganisms, etc. This environment can be controlled by environment control systems such as temperature regulating, ventilating, humidifying, lighting, moving, noise reduction systems, vibration reducing systems, etc. An incubator is, in an embodiment, a deployable incubator as depicted in U.S. Provisional Pat. Appl. 61/940,514, filed 17 Feb. 2014, titled “AN INCUBATOR DEPLOYABLE MULTI-FUNCTIONAL PANEL”, of which is hereby incorporated by reference herein in its entirety. An incubator is, in an embodiment, a transport incubator as depicted in U.S. Provisional Pat. Appl. 61/899,233, filed 3 Nov. 2013, titled “A PATIENT TRANSPORT INCUBATOR”, of which is hereby incorporated by reference herein in its entirety.

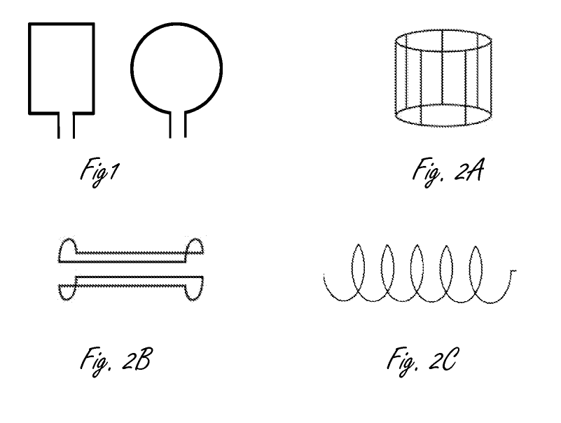

Reference is now made to FIG. 1 which represents surface RF coils. The simplest form of such an RF-transmit coil is a single loop, either circular or rectangular, oriented at right angles to the main magnetic field. By driving a sinusoidal alternating current through this loop at the Larmor frequency, an oscillating magnetic field perpendicular to Bo (magnetic field) is produced. Somewhat more sophisticated variations of this coil can be easily imagined, such as 2-loop (Helmholz) or multi-loop (solenoid) configurations (not shown). The depth of the image of a surface coil is generally limited to about one radius. Surface coils may be used for spines, shoulders, TMJ's, and other relatively small body parts close to the skin surface.

Reference is now made to FIG. 2 which represents different volume RF coils which are designed to provide a homogeneous RF excitation across a large volume. Most clinical MRI scanners include a built in volume coil to perform whole-body imaging, and smaller volume coils have been constructed for the head and other extremities. The RF homogeneity of volume coils is highly desirable for transmit, but is less ideal when the region of interest is small. The large field of view of volume coils means that during receive they receive noise from the whole body, not just the region of interest.

Reference is now made to FIG. 2A which represents a birdcage coil which is the most commonly used RF-transmit device used in clinical MRI today. Virtually all body coils in cylindrical superconducting scanners are of this design. As shown in the diagram, the birdcage coil consists of two circular conductive loops referred to as end rings connected by an even number of conductive straight elements called rungs or legs. The number of rungs depends on the size of the coil (body coil>head coil) and typically ranges from about 8 to 32. Birdcage coils also contain capacitors between conducting elements variably arranged based on the frequency characteristics desired. In clinical MRI a high-pass configuration is generally used with pairs of capacitors located along the end rings. Together this design approximates a continuous conducting surface.

In transmit operation sinusoidal currents are applied to each rung that are sequentially phase shifted around the coil's periphery. If there are N rungs, the phase shift between the currents in neighboring elements is 360°/N. According to antenna theory whenever the current distribution over a cylindrical surface satisfies sinusoidal angular dependence, a resonant condition exists and a homogeneous magnetic field can be created inside the conductor.

Reference is now made to FIG. 2B which represents a saddle coil which is commonly used for imaging of the extremities such as the knee. These coils provide better homogeneity of the RF in the area of interest than a surface of Helmholtz pair and are used as volume coils, unlike surface coils. Paired saddle coils are also used for the x and y gradient coils. By running current in opposite directions in the two halves of the gradient coil, the magnetic field is made stronger near one and weaker near the other.

Reference is now made to FIG. 2C which represents a solenoidal coil which is commonly used when the static magnetic field is perpendicular to the long axis of the body. When a current is passed through the coil, the magnetic field within the coil is relatively uniform.

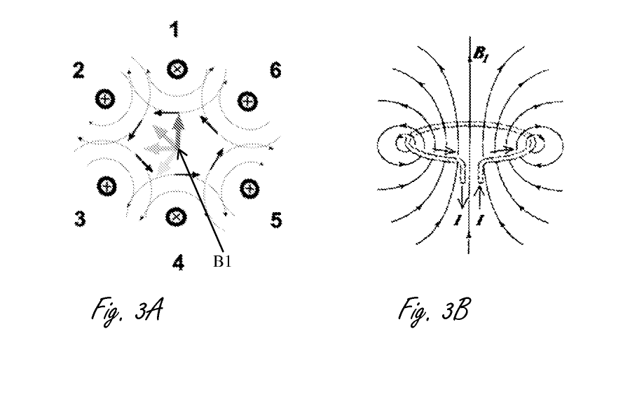

Reference is now made to FIG. 3A which represents the B1 field of a hypothetical 6-rung birdcage coil. The current in each rung is directed into the page (denoted by X arrow ends). The curved local fields generated around each rung are drawn according to Maxwell's right-hand rule. Each rung is driven by a sinusoidal current, but the peak current of each successive rung is delayed by 360°/6=60°. As each rung peaks in turn the central magnetic field is seen to rotate. This is an RF-resonance phenomenon called the first mode, or homogeneous mode of the coil.

Reference is now made to FIG. 3B which represents the B1 field of a surface coil. By driving a sinusoidal alternating current through this loop at the Larmor frequency, an oscillating magnetic field perpendicular to Bo is produced.

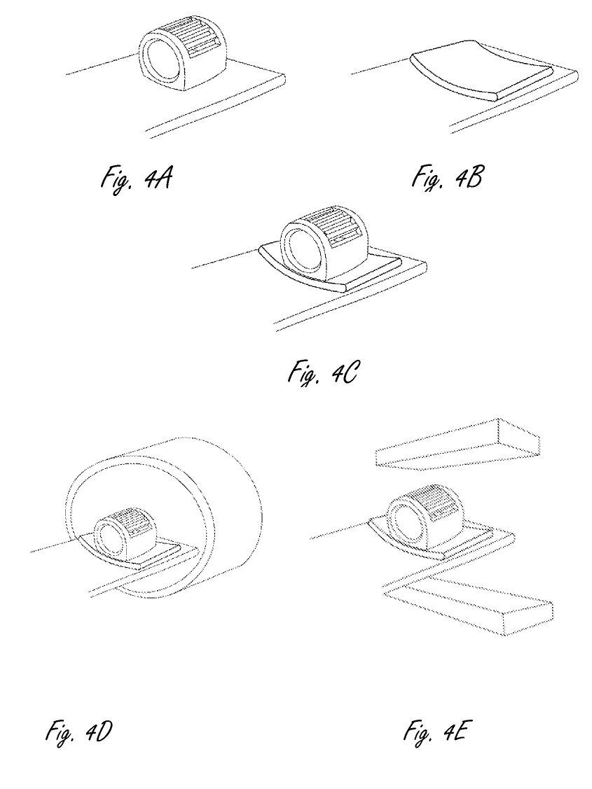

Reference is now made to FIG. 4A which is an illustration representing an RF assembly comprising a volume coil.

Reference is now made to FIG. 4B which is an illustration representing an RF assembly comprising a surface coil.

Reference is now made to FIG. 4C which is an illustration representing an RF assembly comprising a surface coil and a volume coil. The assembly may be maneuverable and/or the surface and volume coils can be maneuverable in respect to each other. Maneuverability may be achieved manually or automatically or a combination of both of them. Maneuvering the coils in respect each other is meant to achieve better SNR and/or to reduce imaging time. In some variants of the invention, the coils can be rotated independently, so that the angles between the coils can be changed at will. In other variants, the angles between the coils are linked. For non-limiting example, a group of coils rotate in tandem; two groups of coils can be coupled to rotate in opposite directions (clockwise vs. counterclockwise); two groups of coils can be coupled so that motion of one group is set to a predetermined fraction of the other (e.g. rotating one group of coils through an angle A moves another group of coils through an angle 0.1A about a predetermined axis relative to the axis of rotation of the first group, and any combination thereof). Therefore, it is possible to move the patient (neonate) and/or the receiver coils so that the volume of interest is located in a desired region in the static magnetic field, so that the receiver coils are positioned so as to provide an optimum combination of high signal to noise ratio (SNR) and high sensitivity, and so that the desired portion of the neonate is optimally located in the region of interest.

In some variants of the invention, the patient (neonate) can be moved through the coils at a predetermined velocity so that the volume of interest within the neonate is scanned with the coils' centers remaining stationary at the point at which their spatial resolution is highest.

In some embodiments of these variants, the coils are rotated during scanning so as to maximize sensitivity, maximize SNR, to have the maximum sensitivity consistent with a given SNR, or the maximum SNR consistent with a given sensitivity.

Reference is now made to FIG. 4D which is an illustration representing an MRD device with a cylindrical magnet electromagnet comprising an RF assembly of combined surface coil and a volume coil;

Reference is now made to FIG. 4E which is an illustration representing an MRI device with a dipolar electromagnet comprising an RF assembly of combined surface coil and a volume coil.

1. A magnetic resonance imaging device (MRD) comprising an RF assembly; said RF assembly is characterized by at least one volume coil and at least one surface coil which are simultaneously operable so that one of the following is being held true:
a. said volume coil and said surface coil as transceivers;
b. said volume coil as transceiver and said surface coil as receiver;
c. said volume coil as transceiver and said surface coil as transmitter;
d. said volume coil and said surface coil as receivers;
e. said volume coil as receiver and said surface coil as transceiver;
f. said volume coil as receiver and said surface coil as transmitter;
g. said volume coil and said surface coil as transmitters;
h. said volume coil as transmitter and said surface coil as transceiver; and
i. said volume coil as transmitter and said surface coil as receiver.

2. The MRD of claim 1, wherein said MRD has an SNR value n times higher than an SNR value of an MRD comprising an RF assembly comprising only a volume coil or a surface coil; n is equal or greater than 1.05.

3. The MRD of claim 1, wherein the imaging time of said MRD is m times lower than an SNR value of an MRD comprising RF assembly comprising only a volume coil or a surface coil; m is equal or greater than 1.05.

4. The MRD of claim 1, wherein said volume coil is selected from a group consisting of birdcage coils, TEM Coil, saddle coil, and any combination thereof.

5. The MRD of claim 1, wherein said RF assembly is maneuverable.

6. The MRD of claim 1, wherein said volume coil and said surface coil are individually maneuverable.

7. The MRD of claim 1, wherein at least one of said volume coil or said surface coil are multi tuned RF coils.

8. The MRD of claim 1, wherein said MRD additionally comprises an incubator adapted to accommodate a neonate.

9. An RF assembly for magnetic resonance imaging device (MRD) characterized by at least one volume coil and at least one surface coil which are simultaneously operable so that one of the following is being held true:
a. said volume coil and said surface coil as transceivers;
b. said volume coil as transceiver and said surface coil as receiver;
c. said volume coil as transceiver and said surface coil as transmitter;
d. said volume coil and said surface coil as receivers;
e. said volume coil as receiver and said surface coil as transceiver;
f. said volume coil as receiver and said surface coil as transmitter;
g. said volume coil and said surface coil as transmitters;
h. said volume coil as transmitter and said surface coil as transceiver; and
i. said volume coil as transmitter and said surface coil as receiver.

10. The RF assembly of claim 9, wherein said MRD comprising said RF assembly has an SNR value n times higher than an SNR value of an MRD comprising an RF assembly comprising only a volume coil or a surface coil; n is equal or greater than 1.05.

11. The RF assembly of claim 9, wherein the imaging time of said MRD comprising said RF assembly value is m times lower than an SNR value of an MRD comprising an RF assembly comprising only a volume coil or a surface coil; m is equal or greater than 1.05.

12. The RF assembly of claim 9, wherein said volume coil is selected from a group consisting of birdcage coils, TEM Coil, saddle coil, and any combination thereof.

13. The RF assembly of claim 9, wherein said RF assembly is combined within a neonate incubator adapted to be accommodated within an MRD.

14. The RF assembly of claim 9, wherein said RF assembly is combined within said MRD.

15. The RF assembly of claim 9, wherein said volume coil is combined within said MRD or within a neonate incubator adapted to be accommodated within said MRD and said surface coil is combined within said MRD or within said incubator.

16. The RF assembly of claim 15, wherein said volume coil or said surface coil is configured to close an opening of said incubator.

17. The RF assembly of claim 9, wherein said RF assembly is maneuverable.

18. The RF assembly of claim 17, wherein said volume coil and said surface coil are individually maneuverable.

19. The RF assembly of claim 9, wherein at least one of said volume coil or said surface coil are multi tuned RF coils.
